(19) United States
(12) Patent Application Publication
(10) Pub. No.: US 2010/0183443 A1
(43) Pub. Date: Jul. 22, 2010

(54) INTEGRATED WIND TURBINE AND SOLAR ENERGY COLLECTOR

(76) Inventor: Steve Thorne, Berkeley, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/355,164

(22) Filed: Jan. 16, 2009

(51) Int. Cl. F03D 11/00; H01L 31/042

(52) U.S. Cl. 416/146 R; 136/244

(57) ABSTRACT

A system for collecting wind and solar energy including a tower, a wind turbine, and a solar energy collector. The solar energy collector has a vertically oriented frame attached to the wind turbine. The solar energy collector is rotatably coupled to the bottom end of the tower to enable the vertically oriented frame and the wind turbine to rotate together about the tower axis. The vertically oriented frame has one or more photovoltaic panels for collecting solar energy. The solar energy collector can act as a wind foil to rotate the attached wind turbine in the direction of the wind. Alternatively, a motor can rotate the solar energy collector and wind turbine.

### BACKGROUND OF THE INVENTION

The present invention relates generally to photovoltaic panels also called solar panels, and more particularly, to the combined use of photovoltaic panels and wind turbines. With concern over global warming, and the realization that major sources of energy such as oil are a limited resource that may be significantly depleted in the foreseeable future, there has been an increased interest in alternative and sustainable energy sources. Two alternative energy sources that have been tapped for nearly pollution free production of electrical energy are wind energy captured using wind turbines, and solar energy collected by photovoltaic (PV) panels. Both methods produce energy without emitting greenhouse gases.

Wind turbines are currently available in many sizes. Small wind turbines for homes, farms, and small businesses have blades that are only a few feet in diameter and produce about 1 kilowatt of power, while large wind turbines have blade diameters of up to 300 feet and generate over 3 megawatts of power. Large wind turbines are often placed together in wind farms which are capable of producing utility-scale power. At the end of 2007, worldwide capacity of wind-powered turbines was 94.1 gigawatts, of which 16.8 gigawatts was produced in the United States. While this represents a small fraction of the total energy consumed in the United States, wind produced energy accounts for 19% of the electricity production in Denmark, 9% in Spain and Portugal, and 6% in Germany and Ireland.

Although wind turbines are a useful source for producing energy, current designs have limitations. For example, wind turbines currently in use have a low energy density and can only produce energy in strong winds. In addition, current designs produce noise that may be disruptive if in close proximity to a residential area.

### BRIEF SUMMARY OF THE INVENTION

According to the present invention, apparatuses and systems related to alternative energy production are provided. More particularly, the present invention relates to a vertically mounted rotatably engaged solar energy collector (“solar energy collector”) having one or more photovoltaic panels. Merely by way of example, the present invention relates to a wind turbine integrated with the solar energy collector to collect both wind and solar energy. However, it would be recognized that the invention has a much broader range of applicability.

An embodiment of the disclosure is directed to a system for collecting wind and solar energy. The system includes a tower having a top end, a bottom end, and a tower axis. The system further includes a wind turbine for collecting wind energy. The wind turbine is rotatably coupled to the top end of the tower. The system further includes a solar energy collector having a vertically oriented frame attached to the wind turbine and rotatably coupled to the bottom end of the tower to enable the vertically oriented frame and the wind turbine to rotate together about the tower axis. The vertically oriented frame contains one or more photovoltaic panels for collecting solar energy.

Another embodiment is directed to a solar energy collector having one or more photovoltaic panels for collecting solar energy and a vertically oriented frame holding the one or more photovoltaic panels. The vertically oriented frame is rotatably coupled to a bottom end of a tower and is attached to a structure rotatably coupled to a top end of a tower having a tower axis. The solar energy collector and the structure are configured to rotate together about the tower axis. The structure may be a wind turbine in some cases.

Another embodiment is directed to a system for collecting wind and solar energy comprising a tower having a top end, a bottom end, and a tower axis. The system further includes a wind turbine for collecting wind energy. The wind turbine is coupled to the top end of the tower. The system further includes one or more solar panel assemblies. Each solar energy collector having a vertically oriented frame rotatably coupled to the bottom end and the top end of the tower to enable the vertically oriented frame to rotate about the tower axis. The vertically oriented frame includes one or more photovoltaic panels for collecting solar energy. The system further includes a motor coupled to the tower and coupled to each solar energy collector. The motor is for rotating each solar energy collector.

Another embodiment is directed to a solar energy collector having one or more photovoltaic panels for collecting solar energy and one or more vertically oriented frames. Each vertically oriented frame holds at least one of the one or more photovoltaic panels. Each vertically oriented frame is rotatably coupled to a bottom end and a top end of a tower to enable the vertically oriented frame to rotate about a tower axis of the tower. Each vertically oriented frame is coupled to a motor mounted to the tower, wherein the motor is configured to rotate each of the one or more vertically oriented frames.

For a further understanding of the nature and advantages of the invention, reference should be made to the following description taken in conjunction with the accompanying figures. It is to be expressly understood, however, that each of the figures is provided for the purpose of illustration and description only and is not intended as a definition of the limits of the embodiments of the present invention.

### BRIEF DESCRIPTION OF THE DRAWINGS

FIG. 1 is a perspective view of an exemplary system having a solar energy collector coupled to a wind turbine, in accordance with an embodiment of the invention.

FIG. 2 is a partial elevational view of a top portion of an exemplary solar energy collector coupled to a wind turbine, in accordance with an embodiment of the invention.

FIG. 3 is a partial perspective view of a bottom portion of an exemplary solar energy collector and a motor, in accordance with an embodiment of the invention.

FIGS. 4A, 4B, and 4C are schematic elevational views of three exemplary frame designs having bracing structures, in accordance with an embodiment of the invention.

FIG. 5A is a perspective view and FIGS. 5B and 5C are sectional views of an exemplary system having two solar panel assemblies in a dual frame configuration, in accordance with an embodiment of the invention.

FIG. 6 is a partial elevational view of a bottom portion of two solar panel assemblies in a dual frame configuration with the motor mounted on top of a platform, in accordance with an embodiment of the invention.

FIG. 7 is a sectional view of air flow around a prior art tower.

FIG. 8 is a sectional view of air flow around an exemplary tower and two solar panel assemblies in a dual frame configuration, in accordance with an embodiment of the invention.

FIG. 9 is a perspective view of an exemplary solar energy collector coupled to a small wind turbine, in accordance with an embodiment of the invention.

### DETAILED DESCRIPTION OF THE INVENTION

Embodiments of the invention are directed to a solar energy collector and a system having a solar energy collector integrated with a wind turbine. Some embodiments include a solar energy collector with a vertically oriented frame holding a photovoltaic panel (e.g., a bifacial solar panel). The solar energy collector can be positioned behind the rotor blades of the wind turbine either by fixing the solar energy collector to the wind turbine or by rotating the solar energy collector using a motor. The system includes a processor that receives data from a wind gage and a light sensor to determine whether it is more efficient to generate energy using the wind turbine, the solar energy collector, or both simultaneously. The processor can also determine an orientation for the solar energy collector and wind turbine for optimal energy production.

Certain embodiments of the invention may provide one or more advantages. One advantage may be that the system provides increased energy production and a higher energy efficiency by collecting solar energy as well as the wind energy at the same site. Another advantage may be that by sharing an energy collection infrastructure, the system may minimize capital expenditures. Another advantage may be that the system provides a more consistent production and even energy flow since there are two sources of energy that can be productive at different times. The photovoltaic panel can collect solar energy when the wind turbine is not producing energy such as when there is no wind or the wind turbine is non-operational for some other reason. The wind turbine can collect wind energy when the photovoltaic panel is nonoperational such as at night. If the tower supporting the wind turbine is cylindrical, locating the solar energy collector behind the tower can reduce the vortex shedding which may reduce turbulence and improve the aerodynamic flow of air around the tower. Reducing vortex shedding may reduce stresses on the tower by reducing the forces caused by vortex shedding. In addition, noise associated with the turbulence may be reduced. Reducing vortex shedding may also improve the efficiency of the wind turbines in a wind farm by improving the flow around each wind turbine tower preserving the wind velocity for harvesting by downstream turbines.

Certain embodiments of the invention may include none, some, or all of the above technical advantages. One or more other technical advantages may be readily apparent to one skilled in the art from the figures, descriptions, and claims included herein.

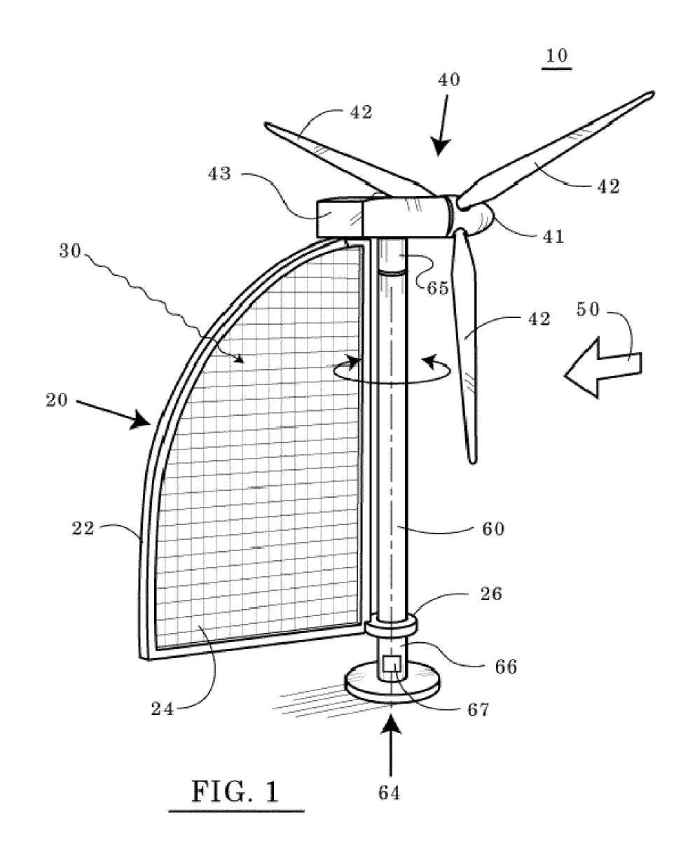

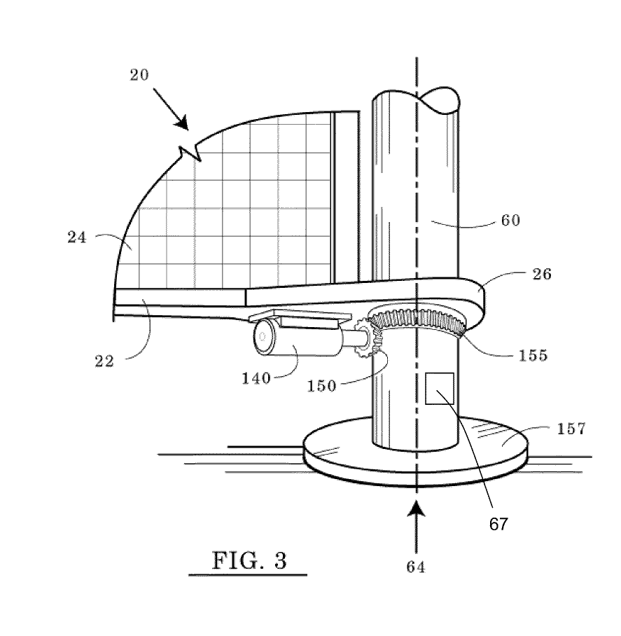

FIG. 1 is a perspective view of an exemplary system 10 having a solar energy collector 20 for capturing solar energy from light 30 (e.g., sunlight), a wind turbine 40 for capturing wind energy from wind 50, and a tower 60 for supporting the solar energy collector 20 and wind turbine 40. The tower 60 has a tower axis 64, a top end 65, a bottom end 66. Tower 60 also has a meter 67 in the bottom end 66 of the tower 60. The solar energy collector 20 includes a frame 22 and a photovoltaic (PV) panel 24 held by the frame 22. The photovoltaic panel 24 converts solar energy from light 30 into electrical energy. The frame 22 is mounted on bearings 26 that allow the solar energy collector 20 to rotate around tower 60 about a tower axis 64. The wind turbine 40 includes a rotor 41 with rotor blades 42 and a towerhead 43. The frame 22 is connected to the underside of the towerhead 43 of the wind turbine 40 opposite the rotor blades 42. The frame 22 is connected to the wind turbine 40 so that the solar energy collector 20 and the wind turbine 40 can rotate together. In this embodiment, the solar energy collector 20 can act as a wind foil and rotate to direct the attached wind turbine 40 substantially parallel to the direction of wind 50. In another embodiment, a motor 140 shown in FIG. 3 can rotate the solar energy collector 20. Although one solar energy collector 20, one wind turbine 40, and one tower 60 are shown in system 10, any suitable number of these apparatuses or other apparatuses may be included in system 10. In addition, light 30 and wind 50 can be from any suitable direction and can originate from any suitable source.

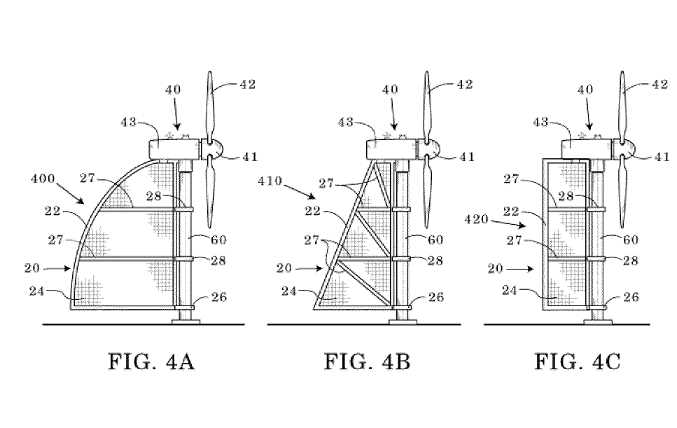

Solar energy collector 20 includes a frame 22 holding a PV panel 24. The frame 22 can be made of any suitable material or materials and can be of any suitable cross sectional shape(s) (e.g., channel section). Frame 22 can include other structures such as bracing structures 27 or stiffening structures (shown in FIGS. 4A, 4B, and 4C). Frame 22 can also be of any suitable design shape. Some examples of suitable designs and their bracing structures are shown in FIGS. 4A, 4B, and 4C.

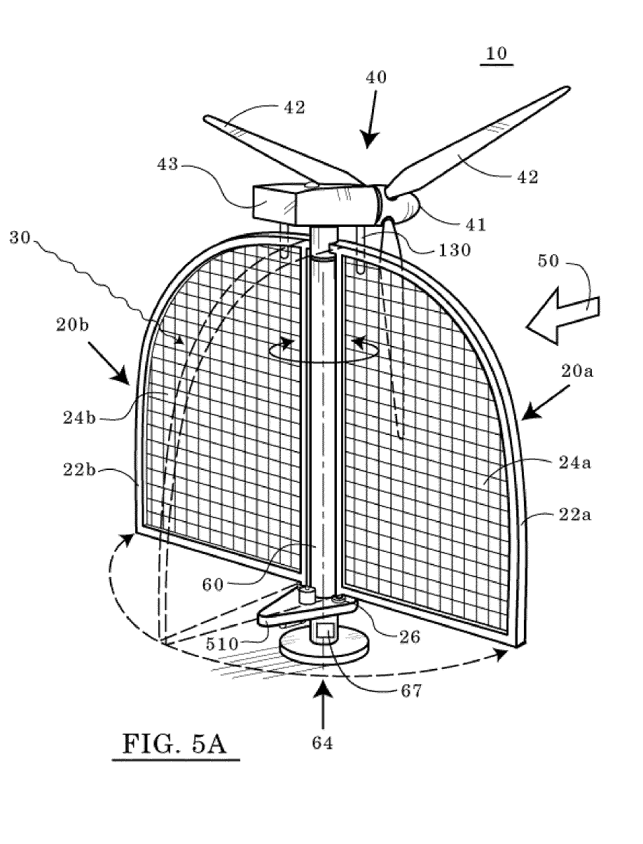

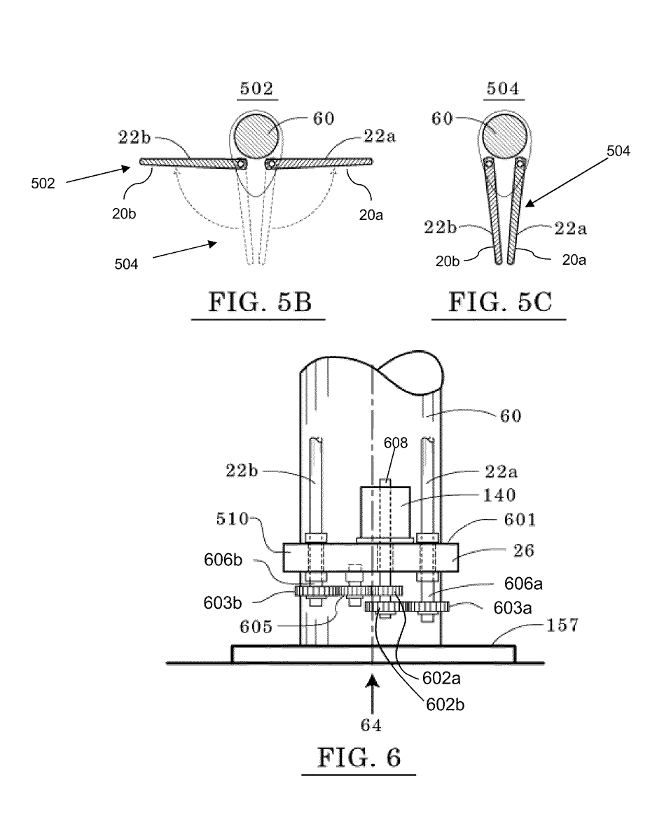

Solar energy collector 20 can include any suitable configuration of frames. In FIG. 1, solar energy collector 20 is a single frame configuration having one frame with a PV panel 24. Other embodiments can have multiple frame configurations. An example of a dual frame configuration having two frames 22a and 22b is shown in FIG. 5A.

A PV panel 24 can refer to an assembly of photovoltaic cells also called solar cells. A photovoltaic cell can refer to any suitable apparatus for converting solar energy from light 30 into electricity by the photovoltaic effect. Any suitable number and type of photovoltaic cells can be included in PV panel 24. Some examples of suitable types of photovoltaic cells include crystalline, semi-crystalline, and flexible. The photovoltaic cells in PV panel 24 are mechanically fastened together and electrically wired together. The front surface of the photovoltaic cells may be covered with a protective material such as glass. The back surface of the photovoltaic cells may be covered with a backing material such as metal, plastic, or fiberglass.

In many embodiments, PV panel 24 is a bifacial solar panel with two back to back surfaces that can collect solar energy and generate power at both surfaces simultaneously. As long as there is light, bifacial solar panels can produce energy because they harvest energy from direct light, from light reflected off the ground and off other surfaces, and from diffuse scattered light from the atmosphere. Some bifacial solar panels allow light to pass through one surface and be captured by the opposite surface. Bifacial solar panels can efficiently collect solar radiation from both sides of the panel even when oriented in a vertical position. An exemplary bifacial solar panel is the HIT double bifacial solar panel produced by SANYO™In other embodiments, PV panel 24 may be a solar panel with a single surface that collects solar energy.

PV panel 24 can be of any suitable size and shape. For example, PV panel 24 can be substantially flat and be approximately the same shape as the frame 22. If the PV panel 24 is smaller that the frame 22, the PV panel 24 may also include a bridging structure to hold the PV panel 24 within the frame 22. PV panel 24 can also include bracing structures 27 (shown in FIGS. 4A-C).

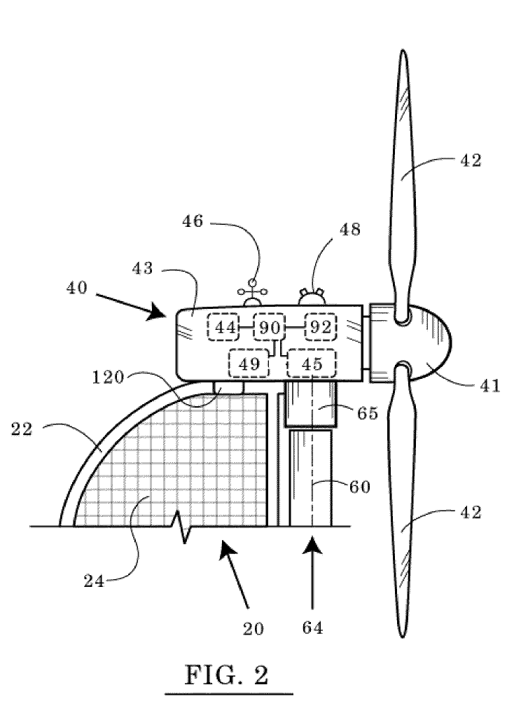

A wind turbine 40 can refer to any suitable apparatus capable of converting kinetic energy from wind 50 into mechanical energy of rotating rotor blades 42 which is converted into electrical energy using a generator 49 (shown in FIG. 2). Wind turbine 40 includes a towerhead 43 rotatably coupled to the top of the tower 60 to allow the wind turbine 40 to rotate about tower axis 64. Solar energy collector 20 is connected to the underside of the towerhead 43 or alternatively, to top end 65. Wind turbine 40 can be of any suitable type of wind turbine. In FIG. 1, wind turbine 40 is a large wind turbine having a high energy production capacity. In FIG. 10, the wind turbine 40 is a small wind turbine with a lower energy production capacity than the large wind turbine.

Wind turbine 40 also includes a rotor 40 having rotor blades 42. The connection of the rotor 41 to the towerhead 43 allows the rotor blades 42 to rotate independently of the towerhead 43. Rotor blades 42 can be of any suitable shape. Some examples of suitable shapes include curved, scooped, U-shaped, V-shaped, or other shapes. Rotor blades 42 can be of any suitable material such as metal, composite, or other suitable material. The rotor 41 may include any suitable number of rotor blades 42. The illustrated example of the rotor 40 shown in FIG. 1 includes three rotor blades 42. Other embodiments of the rotor 41 may include two rotor blades 42, or four or more rotor blades 42.

Tower 60 is a supporting structure for solar energy collector 20 and wind turbine 40. Tower 60 can be of any suitable height for positioning the wind turbine 40 to collect energy from wind 50. Tower 60 can be of any suitable cross sectional shape or shapes. In many of the illustrated embodiments, a center portion of the tower 60 has a circular cross-sectional shape. Tower 60 can be solid, hollow, or a combination thereof. Tower 60 includes a base portion 157 (shown in FIG. 3) that mounts the tower 60 to the ground or other support. The tower 60 also includes a towerhead 43 that can counterbalance rotor 41. The towerhead 43 also includes a housing for internal components of wind turbine 40.

Meter 67 refers to any suitable capable of measuring the energy produced by the solar energy collector 20 and/or wind turbine 40. In some cases, system 10 may include two meters, a meter for measuring the energy produced by the solar energy collector 20 and a meter for measuring the energy produced by wind turbine 40. Meter 67 may include a display for providing output of the measurements of the energy produced by the solar energy collector 20 and/or wind turbine 40. In some cases, the display of meter 67 may show the measurements of the energy produced from the solar energy collector 20, the wind turbine 40, and the total energy produced by both the solar energy collector 20 and the wind turbine 40. Although meter 67 is shown located in the bottom portion of the tower 60, meter 67 may be located in any suitable component of system 10 or may be located separately from system 10.

FIG. 2 is a partial elevational view of a top portion of an exemplary solar energy collector coupled to a wind turbine 40. In the illustrated example, the solar energy collector 20 includes a frame 22 holding a PV panel 24. The solar energy collector 20 also includes an inverter 120 for converting the DC current generated by PV panel 24 into AC current. The wind turbine 40 includes a rotor 41 with rotor blades 40. The rotor 41 is rotatably connected to a towerhead 43. The towerhead 43 has a housing that encloses internal components such as a generator 49, a controller 44, a towerhead motor 45 a processor 90, and memory 92. Any of the internal components may be located externally or located in other components of system 10 in other embodiments. A wind gage 46 for determining the velocity of the wind 50 and a light sensor 48 for sensing light 30 are located and attached to the top surface of the towerhead 43. The wind gage 46 and light sensor 48 may be in other locations on towerhead 43 or on other components of system 10, in other embodiments. In the illustrated example, processor 90 is coupled to controller 44, towerhead motor 45wind gage 46, light sensor 48, and memory 92. Towerhead 43 is fixed to a top end 65 of the tower 60 which can rotate about the tower axis 64.

The towerhead motor 45 is a motor for rotating the towerhead 43. Some large wind turbines may require a towerhead motor 45. In some cases, the towerhead motor 45 may be coordinated with motor 140 in FIG. 3. For example, some embodiments may require that the solar energy collector 20 and wind turbine 40 move together at substantially the same rate of rotation. In these embodiments, the towerhead motor 45 and motor 140 would be coordinated to synchronize the movement of the solar energy collector 20 and wind turbine 40. As another example, towerhead motor 45 may be coordinated to make sure that solar energy collector 20 and the rotors 42 the wind turbine 40 do not collide.

Wind gage 46 (e.g., an anemometer) can refer to any suitable instrument for measuring the speed and the direction of the wind 50. The wind gage 46 can also measure the average wind speed over a predetermined amount of time. Some suitable instruments include a cup anemometer, pitot-static tube, thermal anemometer, hot-wire anemometer, laser Doppler anemometer, and sonic anemometer.

Light sensor 48 (e.g., a photo resistor) can refer to any suitable instrument or instruments for measuring light intensity and the direction of the light 30.

Generator 49 can refer to any suitable device for converting the mechanical energy of the rotating rotor blades 42 into electrical energy.

System 10 also includes memory 92 or other suitable computer readable media. The memory 92 can store code having instructions executed by the processor 90 to perform functions of the system 10. For example, memory 92 may include code for determining whether the wind turbine 40 or the solar energy collector 50 has priority for energy production. This code could include code for determining the threshold value of the wind speed and code for determining whether the wind speed is below or at/above the threshold value. As another example, the memory 92 may include code for determining a direction for the solar energy collector 20 and/or wind turbine 40 for optimal energy production. Processor 90 (e.g., a microprocessor) executes code stored in memory 92 to perform functions of the system 10. Processor 90 can be of any suitable type.

Controller 44 can refer to any device or devices that can control the rotation of the towerhead 43. For example, controller 44 can include a motor that rotates the towerhead 43. In some cases, controller 44 can include a processor coupled to memory storing code with a set of instructions for the processor to execute.

Inverter 120 refers to any device for converting DC current into AC current. In some embodiments, inverter 120 converts the DC current from the PV panel 24 to AC current. Energy from light 30 impacting PV panel 24 produces DC electrical current. This DC current can be converted to AC current using inverter 120 before the connection to the portion of the electrical infrastructure located within the wind turbine 40.

Electrical infrastructure of system 10 can refer to any suitable component(s) for collecting and processing energy from the solar energy collector 20 and wind turbine 40. The electrical infrastructure includes, for example, generator 49, towerhead control 44, towerhead motor 45, processor 90, wind gage 46, and/or light sensor 48. The electrical infrastructure also includes the wiring that connects the components of the electrical infrastructure. The electrical infrastructure can also include the inverter 120 that converts the DC current from PV panel 24 to AC current. In some embodiments, the electrical infrastructure can also include one or more batteries for storing the energy generated by the system 10 and/or to provide energy to electrical components of system 10 such as the motor 140 (shown in FIG. 3) or a processor 90 (shown in FIG. 2). Systems that are off the electrical grid may require batteries to store the energy generated. Meter 67 (shown in FIG. 1) is electrically connected to one or more of the components of electrical infrastructure. In some cases, the meter 67 may be connected downstream of inverter 120.

In one typical scenario, the wind gage 46 sends measurements to the processor 90. If the processor 90 determines from the measurements of the wind speed are below a threshold value, the processor 90 determines that the solar energy collector 20 has priority. The threshold value can refer to a wind speed below which the wind turbine 40 does not efficiently produce energy. The threshold value may be a fixed value or can be determined by processor 90 periodically or on another suitable basis.

If it is determined that the solar energy collector 20 has priority, processor 90 may determine a new direction for optimal solar energy collection. Processor 90 then sends a signal to controller 44 and/or motor 140 to rotate towerhead 43 and the attached solar energy collector 20 into the new direction that maximizes the solar radiation impacting PV panel 24.

When the wind speed measured by wind gage 46 is determined by the processor 90 to be equal or above the threshold value, the processor 90 determines that the wind turbine 40 has priority. If it is determined that the wind turbine 40 has priority, processor 90 may determine a new direction of the wind turbine 40 for optimal wind energy collection. Processor 90 sends a signal to controller 44 and/or motor 140 to rotate towerhead 43 such that rotor blades 42 face into the new direction. In other embodiments, processor 90 may send a signal to motor 140 and/or controller 44 to allow the solar energy collector 20 to act as a wind foil and rotate to direct the attached wind turbine 40 into the direction of the wind 50. The direction of the wind 50 is determined by wind gage 46.

When the wind gage 46 detects a change in direction of the wind 50, the processor 90 may send a signal to the controller 44 or motor 140 to rotate the towerhead 43 so that the rotor blades 42 are directed into the new direction of the wind 50. In some cases, the processor 90 may determine the new direction on a periodic basis. For example, the wind gage 46 may detect wind directions every 5 seconds and processor 90 may determine on a periodic basis (e.g., every 5 minutes) whether the wind direction has changed and the new direction based on the wind gage 46 information. If the wind direction has changed, the processor 90 will send a signal to controller 44 to rotate the towerhead 43 to the new direction.

In some cases, processor 90 may determine a new direction or orientation of the PV panel 24 for optimal solar energy collection. Processor 90 may send a signal to controller 44 to rotate solar energy collector 20 so that PV panel 24 is in the new direction. Processor 90 may determine the new direction based on data provided by light sensor 48. Alternatively, the processor 90 may determine the direction from data stored in memory 92 that considers that considers the time, date, and coordinates where the PV panel 24 is located and directed.

In another embodiment, meter 67 sends measurements of the energy produced by the solar energy collector 20 and wind turbine 40 to the processor 90. If the processor 90 determines that the energy output from the solar energy collector 20 is equal to or more than the energy output from the wind turbine 40, the processor 90 may determine that the solar energy collector 20 has priority. If the processor 90 determines that the energy output from the wind turbine 40 is more than the energy output from the solar energy collector 20, the processor 90 may determine that the wind turbine 40 has priority. If the processor 90 determines that the solar energy collector 20 has priority, the processor 90 may determine a new direction for optimal solar energy collection. Processor 90 then sends a signal to controller 44 and/or motor 140 to rotate towerhead 43 and the attached solar energy collector 20 into the new direction that maximizes the solar radiation impacting PV panel 24. If it is determined that the wind turbine 40 has priority, processor 90 may determine a new direction of the wind turbine 40 for optimal wind energy collection. Processor 90 may then send a signal to controller 44 and/or motor 140 to a) rotate towerhead 43 such that rotor blades 42 face into the new direction, or b) allow the solar energy collector 20 to act as a wind foil.

Controlling the direction of the solar energy collector 20 and/or wind turbine 40 may be advantageous to increasing the rate of power that a wind turbine 40 extracts from the wind 50. The rate of power extracted from the wind 50 is proportional to the cube of the wind speed. By detecting the new direction of the wind 50 using wind gage 46 and positioning the rotor blades 50 in the new direction of the wind, the wind speed and rate of power may be maximized. In addition, reducing obstructions to the wind flow and reducing turbulence in the wind flow to the wind turbine 50 may increase the wind speed and thus may increase the rate of power generated by the wind turbine 50. By making sure that the frame 22 is positioned at the leeward side of the tower 60, the system 10 avoids an obstruction of air flow that could be caused by the frame 22 being placed in front of or to the sides of the tower 60. In addition, placing the frame behind the tower 60 may reduce the vortex shedding from the tower which can reduce turbulence in the air flow. Thus, by controlling the position of the solar energy collector 20 and wind turbine 40, the obstructions and turbulence can be reduced which may increase the wind speed and the rate of power generated by the wind turbine 50 and by wind turbines downstream of wind turbine 50. Further, since the solar energy collector 20 is connected to towerhead 43 opposite the rotor blades 42, collision between them can be avoided.

FIG. 3 is a partial perspective view of a bottom portion of an exemplary solar energy collector 20 and a motor 140. In this example, motor 140 rotates the solar energy collector 20. In some cases, the solar energy collector 20 may be coupled to the wind turbine 40 so that the wind turbine 40 rotates with the solar energy collector 20. The processor 90 and/or controller 44 can determine a final orientation to rotate the solar energy collector 20 to. Processor 90 can send a signal to motor 140 to rotate the solar energy collector 20 to the orientation. The orientation determined by processor 90 and/or controller 44 can be determined to be at a position away from rotor blades. In some cases, the orientation may be determined to maximize the collection of solar energy on PV panel 24.

In FIG. 3, tower 60 includes a base portion 157 that can be used to mount the tower 60 to the ground or other support. Tower 60 also includes a meter 67.

In some cases, towerhead 43 may include one or more safety stops 130 on the towerhead 43 (shown in FIG. 5A) and/or located on tower 60 to prevent frame 22 from rotating beyond a predefined angle or position. For example, there may be one or more stops 130 on tower 60 or towerhead 43 that prevent the frame 22 from rotating more than an angle that is 5 degrees from the vertical plane parallel to the plane of the blades that goes through tower axis 64.

In FIG. 3, the solar energy collector 20 includes a motor 140 mounted under a bottom surface of frame 22. The motor 140 can be any suitable device for rotating the frame around the tower 60 such as a pneumatic device or an electric motor. In the illustrated example, the motor 140 rotates a shaft coupled to a beveled frame gear 150. The teeth of the beveled frame gear 150 are engaged with the teeth of the tower gear 155 which is also beveled. When the shaft of the motor 140 rotates, the beveled frame gear 150 rotates which moves the frame 22 attached to the motor 140 around the tower 60 about the tower axis 64. In other embodiments, other suitable connecting mechanisms can be used to allow motor 140 to rotate solar energy collector 20 around tower 60. In addition, although the motor 140, beveled frame gear 150, and tower gear 155 are located at the bottom of the tower 60 in FIG. 3, these components may be located at any suitable location along the tower 60.

FIGS. 4A, 4B, and 4C are schematic elevational views of three exemplary frame designs 400, 410, and 420 having bracing structures 27. In FIGS. 4A, 4B, and 4C, the wind turbines 40 are rotatably coupled to the top portion of the tower 60 and each of the wind turbines has a rotor 41 with rotor blades 42.

Frame 22 with the first frame design 400 has a horizontal portion, a vertical portion, and a curved portion. Frame 22 is separated into three sections by bracing structures 27 oriented in the horizontal direction. The sections have approximately the same height. The inner section of each of the bracing structures 27 is connected to a connecting structure 28 on the tower 60. Connecting structure 28 can be any suitable structure for connecting the bracing structures 27 to the tower 60. For example, connecting structure 28 may be a bearing or bushing. In some cases, connecting structure may help prevent the solar energy collector 20 from excessively deflecting away from the tower 60. Bracing structures 27 can also include stiffening structures to reduce the deflections of the solar energy collector 20.

Frame 22 with the second frame design 410 has four straight portions. The top portion is short and parallel to the longer bottom portion. Frame 22 includes bracing structures 27 in both the diagonal and horizontal directions.

Frame 22 with the third frame design 420 is generally rectangular in shape with short top and bottom horizontal portions and longer right and left vertical portions. The frame 22 has three sections separated by bracing structures 27 oriented in a horizontal direction. The sections have approximately the same height. The inner section of the bracing structures 27 is connected to a connecting structure 28 on the tower 60.

The bracing structures 27 can refer to any suitable structures for stiffening the PV panels 20 between the frames 22. In some cases, the bracing structures 27 can also support the frames 22. In FIG. 4A for example, the bracing structures 27 are connected to mating structures 28 on tower 60 and may support the forces acting on solar energy collector 20. The bracing structures 27 may be of any suitable material. In some cases, the bracing structures 27 may be of aluminum/steel tubing that is welded or bolted to frames 22.

In another embodiment, solar energy collector 20 may include a frame 22 that consists of a single vertical channel that receives standard PV panels 24. This frame design may be particularly advantageous for small scale systems.

FIG. 5A is a perspective view of an exemplary system 10 having two solar panel assemblies 20a and 20b in a dual frame configuration, a wind turbine 40 for capturing wind energy from wind 50, a motor 140 for rotating the two solar panel assemblies 20a and 20b, and a tower 60 for supporting the solar panel assemblies 20a and 20b and the wind turbine 40. In this dual frame configuration, a first solar energy collector 20a has a first frame 22a holding a first PV panel 24A and second solar energy collector 20b has a second frame 22b holding a second PV panel 24b. Both frames 22a and 22b are rotatably mounted on bearings 26 at the bottom of the tower 60 and rotatably connected to the top of the tower 60 (e.g., by bearings) to allow the solar panel assemblies 20a and 20b to rotate about the their own axes parallel to tower axis 64. In other embodiments, the solar panel assemblies 20a and 20b may be configured to rotate along a horizontal axis.

System 10 also includes a wind turbine 40 having a rotor 41 with rotor blades 42 and a towerhead 43. The rotor 41 is attached to the towerhead 43. The wind turbine 40 also includes stops 130 to prevent frames 22a and 22b from moving in a position that would collide with the rotating rotor blades 42.

System 10 also includes a motor 140 (shown in FIG. 6) mounted underneath a platform 510 of the tower 60. The platform 510 is located at the bottom of the tower 60 below the solar panel assemblies 20a and 20b at to the leeward side of the tower 60. In some cases, motor 140 can be configured to rotate the solar panel assemblies 20a and 20b together. In other cases, motor 140 can be configured to rotate the solar panel assemblies 20a and 20b independently of one another.

In FIGS. 5A and 5B, solar panel assemblies 20a and 20b are shown in an open position 502 by solid lines and in a closed position 504 by phantom lines. In FIG. 5C, the solar panel assemblies 20a and 20b are shown in the closed position. In the open position 502, solar panel assemblies 20a and 20b substantially flank the tower 60. In the closed position, solar panel assemblies 20a and 20b are substantially leeward to the tower 60. The wind turbine 40 is pointed in the direction to the front of the tower 60 which is in the opposite direction from the leeward direction of the tower 60. When the solar panel assemblies 20a and 20b are in the open position 502, the effective area for solar energy collection may be twice the area of the solar panel assemblies 20a and 20b in the closed position 504.

In one scenario, the processor 90 (shown in FIG. 2) may determine whether the solar panel assemblies 20a and 20b have priority or the wind turbine 40 has priority based on data from a wind gage 46 and/or light sensor 48 (shown in FIG. 2). If the processor 90 determines that the wind turbine 40 is more efficient at the time, the processor 90 may determine that the wind turbine 40 has priority. The processor 90 then sends a signal to the motor 140 to move the solar panel assemblies 20a and 20b into the closed position 504. If the processor 90 determines that the solar panel assemblies 20a and 20b have priority, the processor 90 may send a signal to the motor 140 to move the solar panel assemblies 20a and 20b into the open position 502.

FIG. 6 is a partial elevational view of a bottom portion of two solar panel assemblies 20a and 20b in a dual frame configuration with the motor 140 mounted on top of a platform 510. The platform 510 is attached to a side of the tower 60. In most cases, the platform 510 is attached to the opposite side of the tower 60 from the wind turbine 40 (shown in FIG. 5A). The platform 510 has a horizontal surface 601 upon which the motor 140 is mounted. The motor 140 rotates a shaft 608 oriented along a vertical axis. The shaft 608 is located through a hole in the platform 510. The shaft 608 is connected to two motor gears 602a and 602b. The teeth of the motor gear 602a engage with the teeth of the frame gear 603a attached to a rod member 606a of frame 22a. The teeth of motor gear 602b engage with the teeth of central gear 605. The teeth of central gear 605 engage teeth of the frame gear 603b attached to rod member 606b of frame 22b. In one scenario, the motor 140 rotates the shaft 608 which rotates the motor gears 602a and 602b to rotate the frame gears 603 in opposite directions to rotate the solar panels 20a and 20b in opposite directions. In this way, the motor 140 can be used to place the solar panels 20a and 20b in the open position 502, the closed position 504, and/or some angle between the open and closed positions 502 and 504. In FIG. 6, the frames 22a and 22b are shown in the closed position 504.

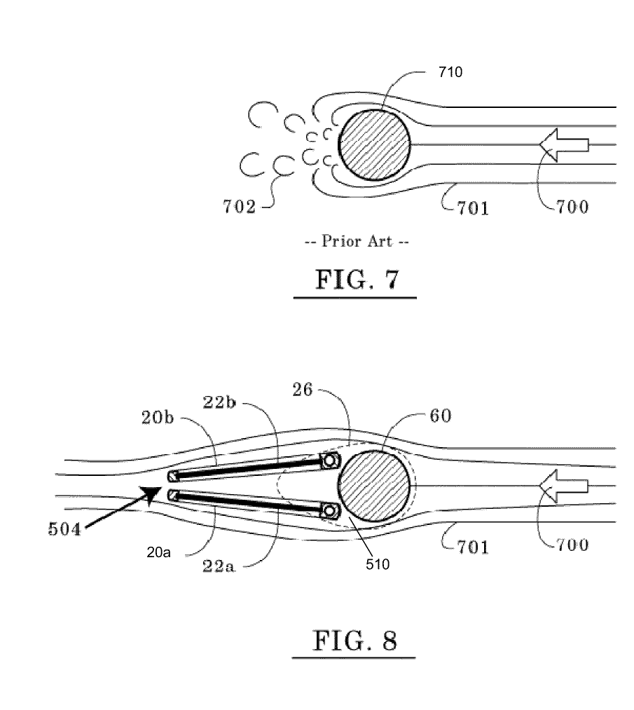

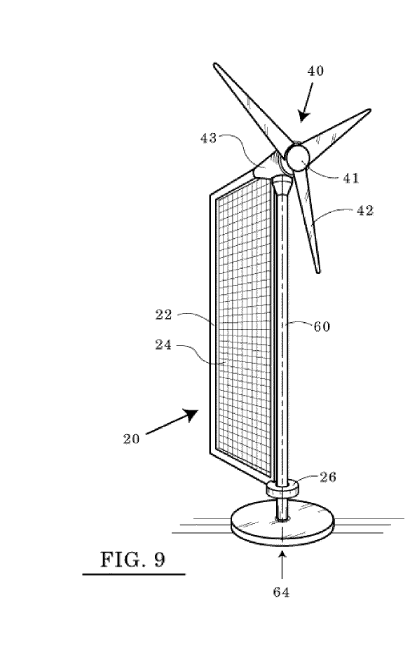

FIG. 7 is a sectional view of air flow around a prior art tower 710 with a circular cross section. A first air flow 700 is shown at a far distance in front of the tower where the flow is laminar and is in a direction toward the prior art tower 710. At a short distance in front of the prior art tower 710, a second air flow 701 is in a direction that is slightly outward as the air flow moves around the prior art tower 710. After the air 50 flows around the prior art tower 710, low-pressure vortices are created at the back (leeward or downstream side) of the prior art tower 710. The vortices are created and detached periodically from either side of the prior art tower 710. The low pressure vortices cause a wake 702 of turbulent flow at the back of the prior art tower 710.

FIG. 8 is a sectional view of air flow around an exemplary tower 60 and two solar panel assemblies 20a and 20b in a dual frame configuration. The tower 60 has a circular cross section and includes a platform 510 upon which the solar panel assemblies 20a and 20b are mounted. In this view, the solar panel assemblies 20a and 20b are shown in the closed position 504. In the closed position 504, solar panel assemblies 20a and 20b are substantially directed to a backward direction opposite the direction that the wind turbine 40 is directed.

A first air flow 700 is shown at a far distance in front of the tower 60 where the flow is laminar and is in a direction toward the tower 60. At a short distance in front of the tower 60, a second air flow 701 is in a direction that is slightly outward where the air is starting to flow around the tower 60. In this embodiment, the air 50 has a streamline flow around the tower 60 and around the solar panel assemblies 20a and 20b in the closed position 504. As shown, the introduction of the solar panel assemblies 20a and 20b may streamline the air flow around the tower 60.

FIG. 10 is an elevational view of an exemplary solar energy collector 20 coupled to a small wind turbine 40. The small wind turbine 40 has a rotor 41 with rotor blades 42 and a towerhead 43 rotatably mounted on the top of the tower 60. The solar energy collector 20 includes a frame 22 and a PV panel 24 held by the frame 22. The frame 22 is mounted on bearings 26 at the bottom of the tower 60 and connected to the towerhead 43 opposite the rotor blades 42 so that the solar energy collector 20 and the wind turbine 40 can rotate together around the tower 60 about a tower axis 64. The solar energy collector 20 can act as a wind foil and rotate to direct the attached wind turbine 40 substantially in the direction of wind 50 without the need for a motor.

It should be understood that the present invention as described above can be implemented in the form of control logic using computer software in a modular or integrated manner. Based on the disclosure and teachings provided herein, a person of ordinary skill in the art will know and appreciate other ways and/or methods to implement the present invention using hardware and a combination of hardware and software.

Any of the software components or functions described in this application, may be implemented as software code to be executed by a processor using any suitable computer language such as, for example, Java, C++or Perl using, for example, conventional or object-oriented techniques. The software code may be stored as a series of instructions, or commands on a computer readable medium, such as a random access memory (RAM), a read only memory (ROM), a magnetic medium such as a hard-drive or a floppy disk, or an optical medium such as a CD-ROM. Any such computer readable medium may reside on or within a single computational apparatus, and may be present on or within different computational apparatuses within a system or network.

A recitation of “a”, “an” or “the” is intended to mean “one or more” unless specifically indicated to the contrary.

The above description is illustrative and is not restrictive. Many variations of the disclosure will become apparent to those skilled in the art upon review of the disclosure. The scope of the disclosure should, therefore, be determined not with reference to the above description, but instead should be determined with reference to the pending claims along with their full scope or equivalents.

One or more features from any embodiment may be combined with one or more features of any other embodiment without departing from the scope of the disclosure. Further, modifications, additions, or omissions may be made to any embodiment without departing from the scope of the disclosure. The components of any embodiment may be integrated or separated according to particular needs without departing from the scope of the disclosure. For example, although separate components are shown for the processor 90 and controller 44, some embodiments integrate the processor 90 and controller 44. As another example, the frame 22 may integrate the tower 60 so that the frame is supporting the wind turbine 40. Moreover, the operations of any embodiments may be performed by more, fewer, or other system components.

What is claimed is:

1. A system for collecting wind and solar energy, comprising:
a tower having a top end, a bottom end, and a tower axis;
a wind turbine for collecting wind energy, the wind turbine rotatably coupled to the top end of the tower; and
a solar energy collector comprising a vertically oriented frame attached to the wind turbine and rotatably coupled to the bottom end of the tower to enable the vertically oriented frame and the wind turbine to rotate together about the tower axis, wherein the vertically oriented frame contains one or more photovoltaic panels for collecting solar energy.

2. The system for collecting wind and solar energy of claim 1, wherein the one or more photovoltaic panels include at least one bifacial solar panel.

3. The system for collecting wind and solar energy of claim 1, wherein the solar energy collector is configured to rotate in response to wind flow to direct the wind turbine substantially in a direction of the wind flow.

4. The system for collecting wind and solar energy of claim 1, further comprising:
a motor mounted to the vertically oriented frame; and
a beveled frame gear engaged with a tower gear on the bottom end of the tower, wherein the motor is operatively coupled to the beveled frame gear to rotate the vertically oriented frame about the tower axis.

5. The system for collecting wind and solar energy of claim 1, further comprising a motor mounted to the vertically oriented frame, the motor operatively coupled to the bottom end of the tower to rotate the vertically oriented frame about the tower axis.6. The system for collecting wind and solar energy of claim 1, wherein:
the wind turbine includes a rear portion opposite a front portion including one or more rotor blades; and
the vertically oriented frame is coupled to the wind turbine at the rear portion.

7. The system for collecting wind and solar energy of claim 1, further comprising an inverter for converting the solar energy collected by the one or more photovoltaic panels into AC power.

8. The system for collecting wind and solar energy of claim 1, wherein the vertically oriented frame is coupled to the bottom end of the tower by bearings.

9. The system for collecting wind and solar energy of claim 1, wherein the wind turbine comprises one or more rotor blades and a generator for generating electricity from a rotation of the one or more rotor blades.

10. The system for collecting wind and solar energy of claim 1, wherein the vertically oriented frame includes a bracing structure.

11. A solar energy collector comprising:
one or more photovoltaic panels for collecting solar energy; and
a vertically oriented frame holding the one or more photovoltaic panels, the vertically oriented frame rotatably coupled to a bottom end of a tower and attached to a structure rotatably coupled to a top end of the tower,
wherein the solar energy collector and the structure are configured to rotate together about a tower axis of the tower.

12. The solar energy collector of claim 11, wherein the structure is a wind turbine for collecting wind energy.

13. The solar energy collector of claim 12, wherein:
the wind turbine includes a rear portion opposite a front portion including one or more rotor blades; and
the vertically oriented frame is coupled to the wind turbine at the rear portion.

14. The solar energy collector of claim 12, wherein the wind turbine comprises one or more rotor blades and a generator for generating electricity from a rotation of the one or more rotor blades.

15. The solar energy collector of claim 11, wherein the solar energy collector is configured to rotate in response to wind flow to direct the wind turbine substantially in a direction of the wind flow.

16. The system for collecting wind and solar energy of claim 11 further comprising:
a motor mounted to the vertically oriented frame; and
a beveled frame gear engaged with a tower gear on the bottom end of the tower, wherein the motor is operatively coupled to the beveled frame gear to rotate the vertically oriented frame about the tower axis.

17. The system for collecting wind and solar energy of claim 11, further comprising a motor mounted to the vertically oriented frame, the motor operatively coupled to the bottom end of the tower to rotate the vertically oriented frame about the tower axis.

18. The solar energy collector of claim 11, wherein the one or more photovoltaic panels include at least one bifacial solar panel.

19. The solar energy collector of claim 11, further comprising an inverter for converting the solar energy collected by the one or more photovoltaic panels into AC power.

20. The solar energy collector of claim 11, wherein the vertically oriented frame is coupled to the bottom end of the tower by bearings.

21. The solar energy collector of claim 11, wherein the vertically oriented frame includes a bracing structure.

22. A system for collecting wind and solar energy, comprising:
a tower having a top end, a bottom end, and a tower axis;
a wind turbine for collecting wind energy, the wind turbine coupled to the top end of the tower;
one or more solar panel assemblies, each solar energy collector comprising a vertically oriented frame rotatably coupled to the bottom end and the top end of the tower to enable the vertically oriented frame to rotate about the tower axis, wherein the vertically oriented frame is coupled to one or more photovoltaic panels for collecting solar energy; and
a motor coupled to the tower and coupled to the one or more solar panel assemblies, the motor for rotating the one or more solar panel assemblies.

23. The system for collecting wind and solar energy of claim 22, wherein the one or more photovoltaic panels include at least one bifacial solar panel.

24. The system for collecting wind and solar energy of claim 22, wherein the one or more solar panel assemblies comprises a first vertically oriented frame and a second vertically oriented frame in a dual frame configuration.

25. The system for collecting wind and solar energy of claim 24, wherein the motor is configured to rotate the first vertically oriented frame and the second vertically oriented frame into an open position and a closed position.

26. The system for collecting wind and solar energy of claim 25, further comprising:
a wind gage for measuring wind speed;
a light sensor for measuring light;
a processor; and
a computer readable medium coupled to the processor, wherein the computer readable medium comprises code for receiving measurements from the wind gage and the light sensor, code for determining whether the wind turbine or solar panel has priority based on the measurements, and code for determining whether to rotate the first vertically oriented frame and the second vertically oriented frame into an open position or a closed position based on whether the wind turbine or the solar panel has priority.

27. The system for collecting wind and solar energy of claim 25, wherein the first vertically oriented frame is substantially parallel to the second frame in the closed position.

28. The system for collecting wind and solar energy of claim 22, further comprising one or more stops coupled to the wind turbine.

29. The system for collecting wind and solar energy of claim 22, further comprising a plurality of motor gears engaged with one or more frame gears, wherein the motor operatively coupled to the plurality of motor gears to rotate the one or more frame gears to rotate the one or more solar panel assemblies about the tower axis.

30. A solar energy collector comprising:
one or more photovoltaic panels for collecting solar energy; and
one or more vertically oriented frames, each of the one or more vertically oriented frames holding the at least one of the one or more photovoltaic panels, each of the one or more vertically oriented frames rotatably coupled to a bottom end and a top end of a tower to enable the vertically oriented frame to rotate about a tower axis of the tower, each of the one or more vertically oriented frames coupled to a motor mounted to the tower, wherein the motor is configured to rotate each of the one or more vertically oriented frames about the tower axis.

31. The solar energy collector of claim 30, wherein the one or more photovoltaic panels include at least one bifacial solar panel.

32. The solar energy collector of claim 30, wherein the one or more vertically oriented frames comprises a first vertically oriented frame and a second vertically oriented frame in a dual frame configuration.

33. The solar energy collector of claim 32, wherein the motor is further configured to rotate the first vertically oriented frame and the second vertically oriented frame into an open position and a closed position.

34. The solar energy collector of claim 33, wherein the first vertically oriented frame is substantially parallel to the second vertically oriented frame in the closed position.
